(19) United States
(12) Patent Application Publication
(10) Pub. No.: US 2025/0102599 A1
(43) Pub. Date: Mar. 27, 2025

(54) SIGNAL SOURCE SPECIFYING APPARATUS, METHOD, PROGRAM, AND RECORDING MEDIUM

(71) Applicant: ADVANTEST CORPORATION, Tokyo (JP)

(72) Inventors: Tomonori YANAGIDA, Miyagi (JP); Yuji OGATA, Miyagi (JP)

(73) Assignee: ADVANTEST CORPORATION, Tokyo (JP)

(21) Appl. No.: 18/710,798

(22) PCT Filed: Sep. 21, 2022
(86) PCT No.: PCT/JP2022/035075

§ 371 Date: Dec. 11, 2024

(30) Foreign Application Priority Data
Dec. 9, 2021 (JP) 2021-199915

(51) Int. Cl. G01R 33/00

(52) U.S. Cl. CPC G01R 33/0023; G01R 33/0094

(57) ABSTRACT

A signal source specifying apparatus receives measurement results from a plurality of sensors that receive, from a plurality of signal sources, signals represented by vectors each having a predetermined direction and measure triaxial components orthogonal to each other to specify positions of the signal sources and the vectors. The signal source specifying apparatus includes a relational matrix recording section, and a position/vector deriving section. The relational matrix recording section records a relational matrix representing a relationship between the measurement results summarized per axis by a number of the sensors and the vectors. The position/vector deriving section derives the positions of the signal sources and the vectors that offer a minimum cost function based on the measurement results and the relational matrix. The positions of the signal sources and the vectors are specified based on a result of derivation by the position/vector deriving section.

### TECHNICAL FIELD

The present invention relates to measuring of a signal such as a magnetic field.

### BACKGROUND ART

There have conventionally been known methods (e.g. LORETA method, MUSIC method (see Patent Literature 3), Lasso method) of estimating the position of a signal source based on a result of measurement of a magnetic field (see Patent Literatures 1, 2, and 3).

### CITATION LIST

### Patent Literature

Patent Literature 1: Japanese Patent Application Publication No. 2016-080427
Patent Literature 2: Japanese Patent Application Publication No. H07-148131
Patent Literature 3: Japanese Patent Application Publication No. 2009-534103

### SUMMARY OF THE INVENTION

### Technical Problem

Incidentally, the LORETA method minimizes the current source distribution subjected to the Laplacian filter and thus allows for estimation to a deeper position, but the estimation of the signal source distribution is blurry. The LORETA method thus makes it difficult to estimate the positions of multiple signal sources.

Meanwhile, the MUSIC method allows for estimation of the positions of multiple signal sources, but it is difficult to estimate the positions of multiple signal sources (hereinafter referred to as “coherent signal sources”) that output signals of the same frequency and phase (or DC (direct current) signals).

Furthermore, the Lasso method is merely known to use a single-axis magnetic sensor such as SQUID, and thus exhibits poor accuracy in estimating the positions of multiple signal sources (including coherent signal sources).

It is hence an object of the present invention to improve the accuracy of estimating the positions of multiple signal sources.

### Means for Solving the Problem

According to the present invention, a signal source specifying apparatus for receiving measurement results from a plurality of sensors that receive, from a plurality of signal sources, signals represented by vectors each having a predetermined direction and measure triaxial components orthogonal to each other to specify positions of the signal sources and the vectors, includes: a relational matrix recording section that records a relational matrix representing a relationship between the measurement results summarized per axis by a number of the sensors and the vectors; and a position/vector deriving section arranged to derive the positions of the signal sources and the vectors that offer a minimum cost function based on the measurement results and the relational matrix, wherein components of the vectors are summarized per axis by a number of grid points in a space at which the signal sources are positioned, the cost function is the sum of an error function and a normalization term, the error function represents the positions of the signal sources and an error between a true value of each vector and a candidate value for the true value, the normalization term is a function of a normalization parameter and an L1 norm of each vector, and the positions of the signal sources and the vectors are specified based on a result of derivation by the position/vector deriving section.

According to the present invention, a signal source specifying apparatus receives measurement results from a plurality of sensors that receive, from a plurality of signal sources, signals represented by vectors each having a predetermined direction and measure triaxial components orthogonal to each other to specify positions of the signal sources and the vectors. A relational matrix recording section records a relational matrix representing a relationship between the measurement results summarized per axis by a number of the sensors and the vectors. A position/vector deriving section derives the positions of the signal sources and the vectors that offer a minimum cost function based on the measurement results and the relational matrix. Components of the vectors are summarized per axis by a number of grid points in a space at which the signal sources are positioned. The cost function is the sum of an error function and a normalization term. The error function represents the positions of the signal sources and an error between a true value of each vector and a candidate value for the true value. The normalization term is a function of a normalization parameter and an L1 norm of each vector. The positions of the signal sources and the vectors are specified based on a result of derivation by the position/vector deriving section.

According to the signal source specifying apparatus of the present invention, the result of derivation by the position/vector deriving section may be specified as the positions of the signal sources and the vectors.

According to the present invention, the signal source specifying apparatus may further include: a clustering section arranged to classify the positions of the signal sources derived by the position/vector deriving section into clusters of the number of the signal sources; a weighted center deriving section arranged to derive a weighted center of the signal sources for each of the clusters; and a weighted averaging section arranged to average, for each of the clusters, the vectors that are derived by the position/vector deriving section in inverse proportion to the distances between the signal sources and the weighted center, wherein the positions of the signal sources may be each specified as the weighted center, and the vectors may be each specified as a result of derivation by the weighted averaging section.

According to the signal source specifying apparatus of the present invention, the classification into the clusters may be performed according to a K-means method.

According to the signal source specifying apparatus of the present invention, each of the measurement results may be a product of the relational matrix and each vector.

According to the signal source specifying apparatus of the present invention, κ-th power of each of the measurement results may be a product of κ-th power of the relational matrix and each vector (where κ>1).

According to the signal source specifying apparatus of the present invention, the relational matrix may be a lead-field matrix.

According to the signal source specifying apparatus of the present invention, the measurement results summarized per axis by the number of the sensors may form a one-column matrix.

According to the signal source specifying apparatus of the present invention, the vectors may form a one-column matrix.

According to the signal source specifying apparatus of the present invention, the error function may be a function of the measurement results, the relational matrix, and the candidate value.

According to the signal source specifying apparatus of the present invention, the error function may be expressed in (1/2)(b−Ha)^{T}(b−Ha), where “b” represents the measurement results, “H” represents the relational matrix, and “a” represents the candidate value.

According to the signal source specifying apparatus of the present invention, the normalization term may be a product of the normalization parameter and the L1 norm of each vector.

According to the signal source specifying apparatus of the present invention, the vectors may be magnetic dipole moments or electric dipole moments.

According to the present invention, a signal source specifying method for receiving measurement results from a plurality of sensors that receive, from a plurality of signal sources, signals represented by vectors each having a predetermined direction and measure triaxial components orthogonal to each other to specify positions of the signal sources and the vectors, includes: recording a relational matrix representing a relationship between the measurement results summarized per axis by a number of the sensors and the vectors; and deriving the positions of the signal sources and the vectors that offer a minimum cost function based on the measurement results and the relational matrix, wherein components of the vectors are summarized per axis by a number of grid points in a space at which the signal sources are positioned, the cost function is the sum of an error function and a normalization term, the error function represents the positions of the signal sources and an error between a true value of each vector and a candidate value for the true value, the normalization term is a function of a normalization parameter and an L1 norm of each vector, and the positions of the signal sources and the vectors are specified based on a result from the deriving of the positions of the signal sources and the vectors.

The present invention is a program of instructions for execution by a computer to perform a signal source specifying process for receiving measurement results from a plurality of sensors that receive, from a plurality of signal sources, signals represented by vectors each having a predetermined direction and measure triaxial components orthogonal to each other to specify positions of the signal sources and the vectors, the signal source specifying process, including: recording a relational matrix representing a relationship between the measurement results summarized per axis by a number of the sensors and the vectors; and deriving the positions of the signal sources and the vectors that offer a minimum cost function based on the measurement results and the relational matrix, wherein components of the vectors are summarized per axis by a number of grid points in a space at which the signal sources are positioned, the cost function is the sum of an error function and a normalization term, the error function represents the positions of the signal sources and an error between a true value of each vector and a candidate value for the true value, the normalization term is a function of a normalization parameter and an L1 norm of each vector, and the positions of the signal sources and the vectors are specified based on a result from the deriving of the positions of the signal sources and the vectors.

The present invention is a non-transitory computer-readable medium including a program of instructions for execution by a computer to perform a signal source specifying process for receiving measurement results from a plurality of sensors that receive, from a plurality of signal sources, signals represented by vectors each having a predetermined direction and measure triaxial components orthogonal to each other to specify positions of the signal sources and the vectors, the signal source specifying process, including: recording a relational matrix representing a relationship between the measurement results summarized per axis by a number of the sensors and the vectors; and deriving the positions of the signal sources and the vectors that offer a minimum cost function based on the measurement results and the relational matrix, wherein components of the vectors are summarized per axis by a number of grid points in a space at which the signal sources are positioned, the cost function is the sum of an error function and a normalization term, the error function represents the positions of the signal sources and an error between a true value of each vector and a candidate value for the true value, the normalization term is a function of a normalization parameter and an L1 norm of each vector, and the positions of the signal sources and the vectors are specified based on a result from the deriving of the positions of the signal sources and the vectors.

### BRIEF DESCRIPTION OF DRAWINGS

FIG. 1 is a perspective view showing voxels V and magnetic sensors MS according to a first embodiment of the present invention;

FIG. 2 is a functional block diagram showing the configuration of a signal source specifying apparatus 1 according to the first embodiment of the present invention;

FIG. 3 is a functional block diagram showing the configuration of the signal source specifying apparatus 1 according to a second embodiment of the present invention; and

FIG. 4 shows clustering of the positions of signal sources S1 to S4 by the clustering section 18a (FIG. 4(a)), derivation of the weighted centers of clusters by the weighted center deriving section 18b (FIG. 4(b)), and derivation of the weighted averages of vectors by the weighted averaging section 18c (FIG. 4(c)).

### MODES FOR CARRYING OUT THE INVENTION

A description will now be given of embodiments of the present invention referring to drawings.

### First Embodiment

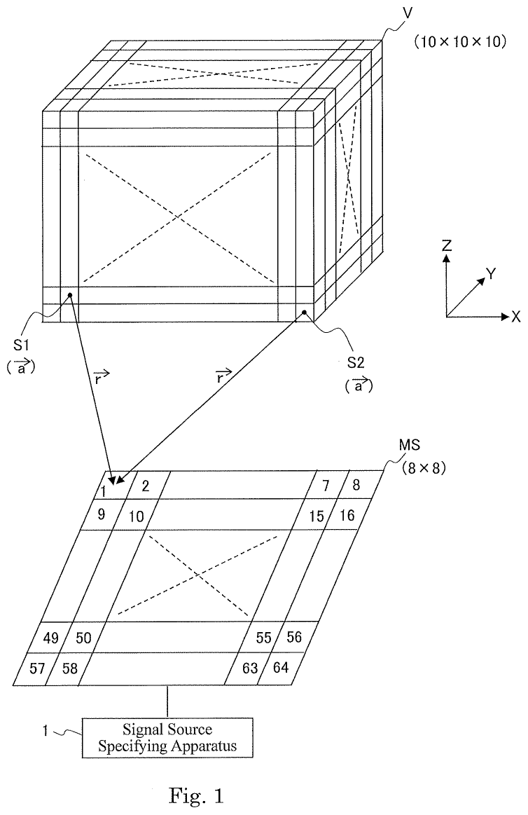

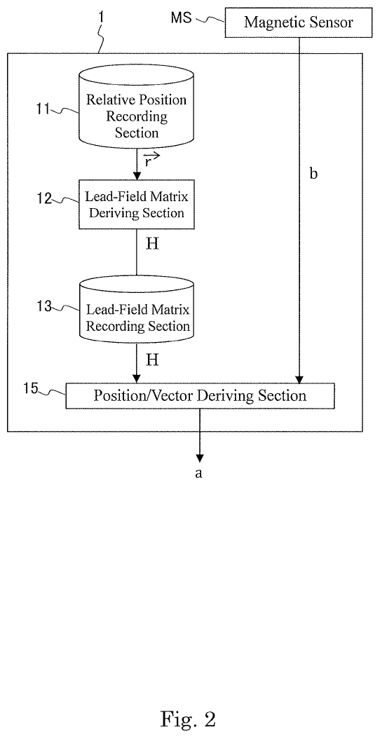

FIG. 1 is a perspective view showing voxels V and magnetic sensors MS according to a first embodiment of the present invention. FIG. 2 is a functional block diagram showing the configuration of a signal source specifying apparatus 1 according to the first embodiment of the present invention.

Referring to FIG. 1, signal sources S1 and S2 output signals. The signals are each represented by a vector “a” having a predetermined direction. The vector “a” is, for example, a magnetic dipole moment. It is noted that the number of signal sources is, for example, two, but may be three or more as long as it is less than the number of magnetic sensors MS. It is also noted that signals output from the signal sources may or may not have their respective frequencies or phases different from each other. That is, signals output from the signal sources may have the same frequency and phase. Further, signals output from the signal sources may be DC (direct current) signals.

The positions within a space at which the signal sources S1 and S2 exist are also represented by voxels V (e.g. 10×10×10=1000 voxels). The signal sources S1 and S2 are positioned within their respective different voxels V. It is noted that the 1000 voxels V are denoted as V1 to V1000.

Multiple (e.g., 64 in 8 rows and 8 columns) magnetic sensors MS are arranged to receive signals (e.g., magnetic dipole moments) and measure X, Y, Z triaxial components bₓ, b_{y}, b_{z} orthogonal to each other. It is noted that the 64 magnetic sensors MS are denoted as MS1 to MS64. Also, the signals are each represented by a vector “a” having a predetermined direction. The multiple magnetic sensors MS are arranged to receive signals from the multiple signal sources S1, S2.

Here given a directional vector “r” from a signal source (magnetic dipole) to a magnetic sensor MS, the magnetic flux density B (function of the vector “r”) measured by the magnetic sensor MS is expressed by Biot-Savart's law as in formula (1), where po is the magnetic constant. The vector “r” can also represent the positional relationship between each of the voxels V (V1 to V1000) and each of the magnetic sensors MS (MS1 to MS64).

$$B ( \vec{r} ) = \frac{{μ}_{0}}{4 π} \{ \frac{3 ( \vec{a} \cdot \vec{r} )}{{\vert \vec{r} \vert}^{5}} \vec{r} - \frac{\vec{a}}{{\vert \vec{r} \vert}^{3}} \} \qquad ( 1 )$$

From formula (1), bₓ is expressed as in formula (2) below, where rₓ, r_{y}, r_{z} are X-, Y-, Z-components of the vector “r”, respectively, and aₓ, a_{y}, a_{z} are X-, Y-, Z-components of the vector “a”, respectively.

$${b}_{x} = \frac{{μ}_{0}}{4 π} \{ ( \frac{3 {r}_{x}^{2}}{{\vert \vec{r} \vert}^{5}} - \frac{1}{{\vert \vec{r} \vert}^{3}} ) {a}_{x} + \frac{3 {r}_{x} {r}_{y}}{{\vert \vec{r} \vert}^{5}} {a}_{y} + \frac{3 {r}_{z} {r}_{x}}{{\vert \vec{r} \vert}^{5}} {a}_{z} \} \qquad ( 2 )$$

$${b}_{x} = {h}_{xx} ( \vec{r} ) {a}_{x} + {h}_{x y} ( \vec{r} ) {a}_{y} + {h}_{xz} ( \vec{r} ) {a}_{z} \qquad ( {2}^{′} )$$

Here, when the coefficients of aₓ, a_{y}, and a_{z} in formula (2) are replaced, respectively, with hₓₓ, h_{xy}, and h_{xz} (the argument is the vector “r”), the formula (2) is expressed as in formula (2′).

From formula (1), b_{y} is expressed as in formula (3) below.

$${b}_{y} = \frac{{μ}_{0}}{4 π} \{ ( \frac{3 {r}_{x} {r}_{y}}{{\vert \vec{r} \vert}^{5}} {a}_{x} + ( \frac{3 {r}_{y}^{2}}{{\vert \vec{r} \vert}^{5}} - \frac{1}{{\vert \vec{r} \vert}^{3}} ) {a}_{y} + \frac{3 {r}_{y} {r}_{z}}{{\vert \vec{r} \vert}^{5}} {a}_{z} \} \qquad ( 3 )$$

$${b}_{y} = {h}_{yx} ( \vec{r} ) {a}_{x} + {h}_{yy} ( \vec{r} ) {a}_{y} + {h}_{yz} ( \vec{r} ) {a}_{z} \qquad ( {3}^{′} )$$

Here, when the coefficients of aₓ, a_{y}, and a_{z} in formula (3) are replaced, respectively, with h_{yx}, h_{yy}, and h_{yz} (the argument is the vector “r”), the formula (3) is expressed as in formula (3′).

From formula (1), b_{z} is expressed as in formula (4) below.

$${b}_{z} = \frac{{μ}_{0}}{4 π} \{ \frac{3 {r}_{z} {r}_{x}}{{\vert \vec{r} \vert}^{5}} {a}_{x} + \frac{3 {r}_{y} {r}_{z}}{{\vert \vec{r} \vert}^{5}} {a}_{y} + ( \frac{3 {r}_{z}^{2}}{{\vert \vec{r} \vert}^{5}} - \frac{1}{{\vert \vec{r} \vert}^{3}} ) {a}_{z} \} \qquad ( 4 )$$

$${b}_{z} = {h}_{zx} ( \vec{r} ) {a}_{x} + {h}_{z y} ( \vec{r} ) {a}_{y} + {h}_{zz} ( \vec{r} ) {a}_{z} \qquad ( {4}^{′} )$$

Here, when the coefficients of aₓ, a_{y}, and a_{z} in formula (4) are replaced, respectively, with h_{zx}, h_{zy}, and h_{zz} (the argument is the vector “r”), the formula (4) is expressed as in formula (4′).

Here, bₓ, b_{y}, b_{z} are expressed as in formula (5) below.

$${b}_{x} = ( \begin{matrix}{b}_{x 1} \\ ⋮ \\ {b}_{x 64}\end{matrix} ) , {b}_{y} = ( \begin{matrix}{b}_{y 1} \\ ⋮ \\ {b}_{y 64}\end{matrix} ) , {b}_{z} = ( \begin{matrix}{b}_{z 1} \\ ⋮ \\ {b}_{z 64}\end{matrix} ) \qquad ( 5 )$$

That is, bₓ is a one-column matrix in which the X components of measurement results from the magnetic sensors MS1 to MS64 are summarized. b_{y} is a one-column matrix in which the Y components of measurement results from the magnetic sensors MS1 to MS64 are summarized. b_{z} is a one-column matrix in which the Z components of measurement results from the magnetic sensors MS1 to MS64 are summarized. For example, bₓ₁, b_{y1}, b_{z1} are the X, Y, Z components of a measurement result from the magnetic sensor MS1, and bₓ₆₄, b_{y64}, b_{z64} are the X, Y, Z components of a measurement result from the magnetic sensor MS64.

Here, the measurement results are summarized per X, Y, Z axis by the number (64) of the magnetic sensors MS as a one-column matrix “b” that consists of bₓ, b_{y}, b_{z} (see the left side of formula (8) and the left side of formula (8′)).

aₓ, a_{y}, a_{z} are also expressed as in formula (6) below.

$${a}_{x} = ( \begin{matrix}{a}_{x 1} \\ ⋮ \\ {a}_{x 1000}\end{matrix} ) , {a}_{y} = ( \begin{matrix}{a}_{y 1} \\ ⋮ \\ {a}_{y 1000}\end{matrix} ) , {a}_{z} = ( \begin{matrix}{a}_{z 1} \\ ⋮ \\ {a}_{z 1000}\end{matrix} ) \qquad ( 6 )$$

That is, each of the components aₓ, a_{y}, a_{z} of the vector “a” is a one-column matrix that has components by the number (1000) of the grid points (voxels) in the space at which the signal sources S1, S2 are positioned. For example, aₓ₁, a_{y1}, a_{z1} are the X, Y, Z components of the vector “a” at the voxel V1, and aₓ₁₀₀₀, a_{y1000}, a_{z1000} are the X, Y, Z components of the vector “a” at the voxel V1000.

Here, the vector “a” is a one-column matrix. In addition, the components aₓ, a_{y}, a_{z} of the vector “a” are summarized per X, Y, Z axis by the number (1000) of the grid points in the space at which the signal sources are positioned (see the right-hand matrices in the right sides of formulae (8) and (8′)).

Referring to FIG. 2, the signal source specifying apparatus 1 according to the first embodiment includes a relative position recording section 11, a lead-field matrix deriving section 12, a lead-field matrix recording section 13, and a position/vector deriving section 15.

The signal source specifying apparatus 1 is arranged to receive measurement results from the multiple sensors MS1 to MS64 and specify the positions of the signal sources S1, S2 and the vector “a”.

The relative position recording section 11 is arranged to record a vector “r” as a relative position between each of the 1000 voxels V and each of the magnetic sensors MS (MS1 to MS64).

The lead-field matrix deriving section 12 is arranged to read the vector “r” from the relative position recording section 11 and obtain hₓ, h_{y}, hₓ, h_{yx}, h_{yy}, h_{yz}, h_{zx}, h_{zy}, h_{zz} (the argument is the vector “r”) (components of a relational matrix “H” to be described hereinafter (e.g. a lead-field matrix)) (see formulae (2) to (4) and (2′) to (4′)).

For example, hₓₓ is expressed as in formula (7) below.

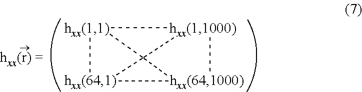

The vector “r” is determined by the position of each voxel V and the position of each magnetic sensor MS and thereby has 1000×64 different candidate values. Accordingly, the first coefficient vₓ₁ also has 1000×64 different candidate values. In formula (7), the 1st row denotes hₓₓ for the magnetic sensor MS1, the 2nd row denotes hₓ, for the magnetic sensor MS2, . . . , and the 64th row denotes hₓₓ for the magnetic sensor MS64. Further, in formula (7), the 1st column denotes hₓₓ for the voxel V1, the 2nd column denotes hₓₓ for the voxel V2, . . . , and the 1000th column denotes hₓₓ for the voxel V1000. For example, the element hₓₓ (1, 1000) of the 1st row and the 1000th column in formula (7) denotes hₓₓ for the magnetic sensor MS1 and the voxel V1000. That is, hₓₓ(1, 1000) can be obtained by substituting the vector “r” as a directional vector from the voxel V1000 to the magnetic sensor MS1 into the coefficient of aₓ in formula (2).

h_{xy}, h_{xz}, h_{yx}, h_{yy}, h_{yz}, h_{zx}, h_{zy}, h_{zz} also each have 1000×64 different candidate values, similarly.

Here, formulae (2′) to (4′) can be expressed as in formula (8) below.

$$[ \begin{matrix}{b}_{x} \\ {b}_{y} \\ {b}_{z}\end{matrix} ] = [ \begin{matrix}{h}_{x x} ( \vec{r} ) & {h}_{x y} ( \vec{r} ) & {h}_{x z} ( \vec{r} ) \\ {h}_{y x} ( \vec{r} ) & {h}_{y y} ( \vec{r} ) & {h}_{y z} ( \vec{r} ) \\ {h}_{z x} ( \vec{r} ) & {h}_{Z} ( \vec{r} ) & {h}_{zz} ( \vec{r} )\end{matrix} ] [ \begin{matrix}{a}_{x} \\ {a}_{y} \\ {a}_{z}\end{matrix} ] \qquad ( 8 )$$

$$b = Ha \qquad ( {8}^{′} )$$

The left side of formula (8) is also defined as “b” (i.e. measurement results summarized per X, Y, Z axis by the number (64) of the magnetic sensors). The measurement result “b” is a one-column matrix.

Further, the right-hand matrix in the right side of formula (8) is the vector “a” (the components aₓ, a_{y}, a_{z} of the vector “a” are summarized per X, Y, Z axis by the number (1000) of grid points in the space at which the signal sources S1, S2 are positioned). The vector “a” is a one-column matrix.

The left-hand matrix in the right side of formula (8) is defined as “H”. “H” is a relational matrix (e.g. a lead-field matrix) that represents the relationship between the measurement result “b” and the vector “a”.

Formula (8) can then be expressed as in formula (8′). That is, the measurement result “b” is a product of the relational matrix “H” and the vector “a”.

As described heretofore, the lead-field matrix deriving section 12 is arranged to obtain components of the relational matrix “H” and further derive the relational matrix (the lead-field matrix) “H”.

The lead-field matrix recording section 13 is arranged to receive and record the relational matrix (the lead-field matrix) “H” from the lead-field matrix deriving section 12.

The position/vector deriving section 15 is arranged to derive the positions of the signal sources S1, S2 and the vector “a” that offer a minimum cost function based on the measurement result “b” and the relational matrix “H”.

That is, the position/vector deriving section 15 is arranged to derive the vector “a” that satisfies formula (9) below.

$$a = {arg min}_{a} [ \frac{1}{2} {( b - H a )}^{T} ( b - H a ) + λ {‖ a ‖}_{1} ] \qquad ( 9 )$$

The cost function is the sum of the error function and the normalization term.

The error function represents the positions of the signal sources S1, S2 and an error between a true value of the vector “a” and a candidate value for the true value. The error function is a function of the measurement result “b”, the relational matrix “H”, and the candidate value “a” (for the true value of the vector). The error function is, for example, (1/2)(b−Ha)^{T}(b−Ha).

The normalization term is a function of a normalization parameter k and an L1 norm of the vector “a”. For example, the normalization term is a product of the normalization parameter k and the L1 norm of the vector “a”.

The positions of the signal sources S1, S2 and the vector “a” are specified based on a result “a” of derivation by the position/vector deriving section 15. For example, the result “a” of derivation by the position/vector deriving section 15 is specified as the positions of the signal sources and the vector. For example, when the signal source S1 is positioned within the voxel V500 and the signal source S2 is positioned within the voxel V600, (aₓ₅₀₀, a_{y500}, a_{z500}) in the result “a” of derivation is the signal vector output from the signal source S1 and (aₓ₆₀₀, a_{y600}, a_{z600}) is the signal vector output from the signal source S2.

Next will be described an operation according to the first embodiment.

The lead-field matrix deriving section 12 reads a vector “r” out of the relative position recording section 11 and derives components hₓₓ, h_{xy}, h_{xz}, h_{yx}, h_{yy}, h_{yz}, h_{zx}, h_{zy}, h_{zz} of a relational matrix (a lead-field matrix) “H” (see formulae (2) to (4) and (2′) to (4′)).

The lead-field matrix recording section 13 receives and records the relational matrix “H” from the lead-field matrix deriving section 12.

The position/vector deriving section 15 is arranged to derive the positions of the signal sources S1, S2 and the vector “a” that offer a minimum cost function based on the measurement result “b” and the relational matrix “H” (see formula (9)).

In accordance with the first embodiment, the accuracy of estimating the positions of multiple signal sources (including coherent signal sources) is improved. That is, since the first embodiment is based on the Lasso method, it is possible to estimate the position of even a coherent signal source. Additionally, in accordance with the first embodiment, since the measurement result “b” and the vector “a” are summarized per X, Y, Z axis (see formulae (8) and (8′)) and such triaxial measurement results can be utilized, the accuracy of estimating the positions of multiple signal sources is improved.

### Second Embodiment

The signal source specifying apparatus 1 according to a second embodiment differs from the signal source specifying apparatus 1 according to the first embodiment in that a clustering section 18a, a weighted center deriving section 18b, and a weighted averaging section 18c are included.

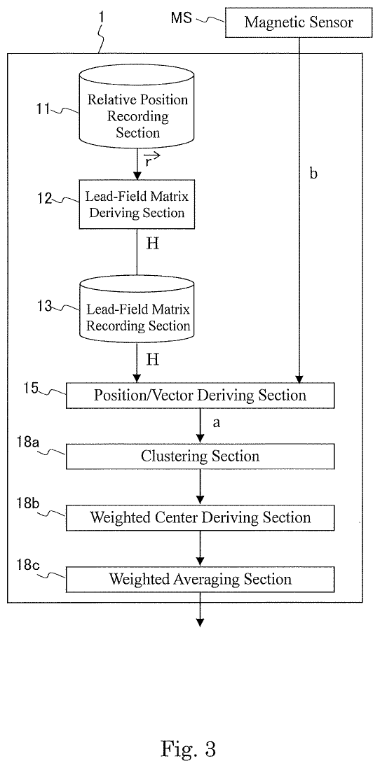

FIG. 3 is a functional block diagram showing the configuration of the signal source specifying apparatus 1 according to the second embodiment of the present invention. The signal source specifying apparatus 1 according to the second embodiment includes a relative position recording section 11, a lead-field matrix deriving section 12, a lead-field matrix recording section 13, a position/vector deriving section 15, a clustering section 18a, a weighted center deriving section 18b, and a weighted averaging section 18c.

The relative position recording section 11, the lead-field matrix deriving section 12, the lead-field matrix recording section 13, and the position/vector deriving section 15 are the same as those in the first embodiment and will not be described.

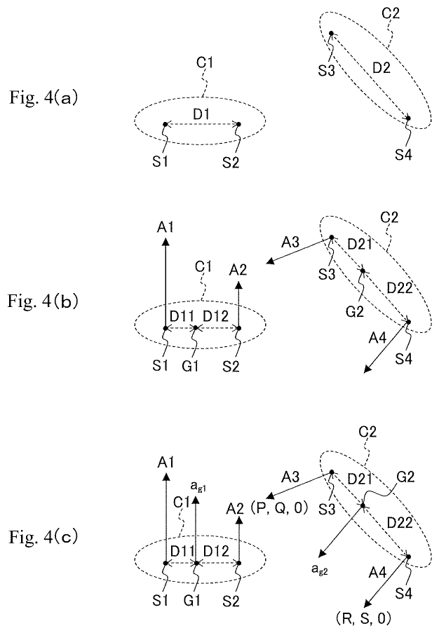

FIG. 4 shows clustering of the positions of signal sources S1 to S4 by the clustering section 18a (FIG. 4(a)), derivation of the weighted centers of clusters by the weighted center deriving section 18b (FIG. 4(b)), and derivation of the weighted averages of vectors by the weighted averaging section 18c (FIG. 4(c)). Note here that the signal sources S1, S2 are not shown in FIGS. 4(b) and 4(c).

Referring to FIG. 4(c), the position G1 represents the true position of a signal source and a_{g1} represents the signal vector. However, when the position G1 does not correspond to a voxel, the positions of signal sources are erroneously derived as S1 and S2. Further, the signal vectors are erroneously derived as A1 and A2.

Further, the position G2 represents the true position of a signal source and a_{g2} represents the signal vector. However, when the position G2 does not correspond to a voxel, the positions of signal sources are erroneously derived as S3 and S4. Further, the signal vectors are erroneously derived as A3 and A4.

Such results of derivation (S1 to S4 and A1 to A4) by the position/vector deriving section 15 are used to obtain the true positions G1, G2 of signal sources and the true signal vectors a_{g1}, a_{g2}.

First, referring to FIG. 4(a), the clustering section 18a is arranged to classify the positions of signal sources S1 to S4 derived by the position/vector deriving section 15 into clusters of the number (two) of signal sources. In the example of FIG. 4(a), the positions of signal sources S1 and S2 are classified into a cluster C1 and the positions of signal sources S3 and S4 are classified into a cluster C2. It is noted that the distance between the positions of the signal sources S1 and S2 is defined as D1 and the distance between the positions of the signal sources S3 and S4 is defined as D2.

Next, referring to FIG. 4(b), the weighted center deriving section 18b is arranged to derive the weighted center of signal sources for each of the clusters. The weighted center G1 of signal sources in the cluster C1 is on a line segment connecting the positions of the signal sources S1 and S2. It is noted that S1G1/S2G1=(the magnitude of A2)/(the magnitude of A1). The weighted center G2 of signal sources in the cluster C2 is on a line segment connecting the positions of the signal sources S3 and S4. It is noted that S3G2/S4G2=(the magnitude of A4)/(the magnitude of A3).

It is noted that the classification into clusters may be performed according to a K-means method. In this case, two weighted centers are first randomly arranged, and then the positions of the signal sources S1 to S4 are classified into clusters according to the distances between the weighted centers and the positions of the signal sources S1 to S4.

Further, the weighted centers of the signal sources are derived for each of the clusters, and then the positions of the signal sources S1 to S4 are classified into clusters according to the distances between the weighted centers derived and the positions of the signal sources S1 to S4. Such derivation of weighted centers and classification into clusters are repeated until the weighted centers derived are in the same positions, respectively, as the weighted centers just before the derivation.

The positions of the signal sources are specified as the weighted centers G1, G2 thus derived.

Further, referring to FIG. 4(c), the weighted averaging section 18c is arranged to average, for each of the clusters, the vector “a” that is derived by the position/vector deriving section 15 in inverse proportion to the distances between the signal sources and the weighted centers.

Taking the cluster C2 as an example, if vector A3 is (P, Q, 0) and the vector A4 is (R, S, 0), the true signal vector a_{g2} is defined as ((P*D22+R*D21)/D2, (Q*D22+S*D21)/D2, 0). It is noted that the same applies to the cluster C1 and the description thereof is omitted.

The signal vector is specified as the weighted average ((P*D22+R*D21)/D2, (Q*D22+S*D21)/D2, 0) thus derived.

Next will be described an operation according to the second embodiment.

First, the operations of the relative position recording section 11, the lead-field matrix deriving section 12, the lead-field matrix recording section 13, and the position/vector deriving section 15 are the same as those in the first embodiment and will not be described.

An output from the position/vector deriving section 15 is provided to the clustering section 18a and the positions of signal sources S1 to S4 are clustered (see FIG. 4(a)). Next, the weighted center deriving section 18b derives the weighted centers of clusters C1, C2 (see FIG. 4(b)). The weighted centers G1, G2 are true positions of the signal sources. Finally, the weighted averaging section 18c derives the weighted averages of vectors (see FIG. 4(c)). The weighted averages a_{g1}, a_{g2} are true signal vectors.

In accordance with the second embodiment, even when the position of a signal source does not correspond to a voxel, the position of the signal source and the signal vector can be obtained.

It is noted that the signal may be an electric dipole moment, though have been a magnetic dipole moment in the above-described embodiments.

It is also noted that the κ-th power of the measurement result “b” may be a product of the κ-th power of the relational matrix “H” and the vector “a” (where x>1) (see formula (10) below), though the measurement result “b” has been a product of the relational matrix “H” and the vector “a” in the above-described embodiments.

$${b}^{κ} = {H}^{κ} a \qquad ( 10 )$$

While the vector “a” have been a function of the measurement result “b” and the relational matrix “H” in the above-described embodiments (e.g. a=f(b, H)), when the κ-th power of the measurement result “b” is a product of the κ-th power of the relational matrix “H” and the vector “a”, it is possible to derive the vector “a” by plugging in the κ-th power of “b” and the κ-th power of “H”, respectively, for “b” and “H” of a=f(b, H).

The above-described embodiment may also be implemented as follows. A computer including a CPU, a hard disk, and a medium (USB memory, CD-ROM, or the like) reading device is caused to read a medium with a program recorded thereon that achieves the above-described components (e.g. the relative position recording section 11, the lead-field matrix deriving section 12, the lead-field matrix recording section 13, the position/vector deriving section 15, the clustering section 18a, the weighted center deriving section 18b, and the weighted averaging section 18c) and install the program in the hard disk. The above-described features can also be achieved in this manner.

### DESCRIPTION OF REFERENCE NUMERAL

1 Signal Source Specifying Apparatus
11 Relative Position Recording Section
12 Lead-Field Matrix Deriving Section
13 Lead-Field Matrix Recording Section
15 Position/Vector Deriving Section
18a Clustering Section
18b Weighted Center Deriving Section
18c Weighted Averaging Section
MS Magnetic Sensor
V Voxel
B Magnetic Flux Density
H Relational Matrix (Lead-Field Matrix)
S1, S2 Signal Source
a Vector (Magnetic Dipole Moment)

1. A signal source specifying apparatus for receiving measurement results from a plurality of sensors that receive, from a plurality of signal sources, signals represented by vectors each having a predetermined direction and measure triaxial components orthogonal to each other to specify positions of the signal sources and the vectors, the signal source specifying apparatus, comprising:
a relational matrix recording section that records a relational matrix representing a relationship between the measurement results summarized per axis by a number of the sensors and the vectors; and
a position/vector deriving section arranged to derive the positions of the signal sources and the vectors that offer a minimum cost function based on the measurement results and the relational matrix, wherein
components of the vectors are summarized per axis by a number of grid points in a space at which the signal sources are positioned,
the cost function is the sum of an error function and a normalization term,
the error function represents the positions of the signal sources and an error between a true value of each vector and a candidate value for the true value,
the normalization term is a function of a normalization parameter and an L1 norm of each vector, and
the positions of the signal sources and the vectors are specified based on a result of derivation by the position/vector deriving section.

2. The signal source specifying apparatus according to claim 1, wherein
the result of derivation by the position/vector deriving section is specified as the positions of the signal sources and the vectors.

3. The signal source specifying apparatus according to claim 1, further comprising:
a clustering section arranged to classify the positions of the signal sources derived by the position/vector deriving section into clusters of the number of the signal sources;
a weighted center deriving section arranged to derive a weighted center of the signal sources for each of the clusters; and
a weighted averaging section arranged to average, for each of the clusters, the vectors that are derived by the position/vector deriving section in inverse proportion to the distances between the signal sources and the weighted center, wherein
the positions of the signal sources are each specified as the weighted center, and
the vectors are each specified as a result of derivation by the weighted averaging section.

4. The signal source specifying apparatus according to claim 3, wherein
the classification into the clusters is performed according to a K-means method.

5. The signal source specifying apparatus according to claim 1, wherein
each of the measurement results is a product of the relational matrix and each vector.

6. The signal source specifying apparatus according to claim 1, wherein
κ-th power of each of the measurement results is a product of κ-th power of the relational matrix and each vector (where κ>1).

7. The signal source specifying apparatus according to claim 1, wherein
the relational matrix is a lead-field matrix.

8. The signal source specifying apparatus according to claim 1, wherein
the measurement results summarized per axis by the number of the sensors form a one-column matrix.

9. The signal source specifying apparatus according to claim 1, wherein
the vectors form a one-column matrix.

10. The signal source specifying apparatus according to claim 1, wherein
the error function is a function of the measurement results, the relational matrix, and the candidate value.

11. The signal source specifying apparatus according to claim 10, wherein
the error function is expressed in (1/2)(b−Ha)^{T}(b−Ha), where “b” represents the measurement results, “H” represents the relational matrix, and “a” represents the candidate value.

12. The signal source specifying apparatus according to claim 1, wherein
the normalization term is a product of the normalization parameter and the L1 norm of each vector.

13. The signal source specifying apparatus according to claim 1, wherein
the vectors are magnetic dipole moments or electric dipole moments.

14. A signal source specifying method for receiving measurement results from a plurality of sensors that receive, from a plurality of signal sources, signals represented by vectors each having a predetermined direction and measure triaxial components orthogonal to each other to specify positions of the signal sources and the vectors, the signal source specifying method, comprising:
recording a relational matrix representing a relationship between the measurement results summarized per axis by a number of the sensors and the vectors; and
deriving the positions of the signal sources and the vectors that offer a minimum cost function based on the measurement results and the relational matrix, wherein
components of the vectors are summarized per axis by a number of grid points in a space at which the signal sources are positioned,
the cost function is the sum of an error function and a normalization term,
the error function represents the positions of the signal sources and an error between a true value of each vector and a candidate value for the true value,
the normalization term is a function of a normalization parameter and an L1 norm of each vector, and
the positions of the signal sources and the vectors are specified based on a result from the deriving of the positions of the signal sources and the vectors.

15. A program of instructions for execution by a computer to perform a signal source specifying process for receiving measurement results from a plurality of sensors that receive, from a plurality of signal sources, signals represented by vectors each having a predetermined direction and measure triaxial components orthogonal to each other to specify positions of the signal sources and the vectors, the signal source specifying process, comprising:
recording a relational matrix representing a relationship between the measurement results summarized per axis by a number of the sensors and the vectors; and
deriving the positions of the signal sources and the vectors that offer a minimum cost function based on the measurement results and the relational matrix, wherein
components of the vectors are summarized per axis by a number of grid points in a space at which the signal sources are positioned,
the cost function is the sum of an error function and a normalization term,
the error function represents the positions of the signal sources and an error between a true value of each vector and a candidate value for the true value,
the normalization term is a function of a normalization parameter and an L1 norm of each vector, and
the positions of the signal sources and the vectors are specified based on a result from the deriving of the positions of the signal sources and the vectors.

16. A non-transitory computer-readable medium including a program of instructions for execution by a computer to perform a signal source specifying process for receiving measurement results from a plurality of sensors that receive, from a plurality of signal sources, signals represented by vectors each having a predetermined direction and measure triaxial components orthogonal to each other to specify positions of the signal sources and the vectors, the signal source specifying process, comprising:
recording a relational matrix representing a relationship between the measurement results summarized per axis by a number of the sensors and the vectors; and
deriving the positions of the signal sources and the vectors that offer a minimum cost function based on the measurement results and the relational matrix, wherein
components of the vectors are summarized per axis by a number of grid points in a space at which the signal sources are positioned,
the cost function is the sum of an error function and a normalization term,
the error function represents the positions of the signal sources and an error between a true value of each vector and a candidate value for the true value,
the normalization term is a function of a normalization parameter and an L1 norm of each vector, and
the positions of the signal sources and the vectors are specified based on a result from the deriving of the positions of the signal sources and the vectors.
